(19) United States
(12) Patent Application Publication
(10) Pub. No.: US 2018/0016673 A1
(43) Pub. Date: Jan. 18, 2018

(54) IMPRINT TEMPLATE MANUFACTURING APPARATUS

(71) Applicants: SHIBAURA MECHATRONICS CORPORATION, Yokohama-shi (JP); TOSHIBA MEMORY CORPORATION, Minato-ku (JP)

(72) Inventors: Satoshi NAKAMURA, Yokohama-shi (JP); Kensuke DEMURA, Yokohama-shi (JP); Daisuke MATSUSHIMA, Yokohama-shi (JP); Masayuki HATANO, Minato-ku (JP); Hiroyuki KASHIWAGI, Minato-ku (JP); Chen KANG, Yokohama-shi (JP); Ganachev Ivan PETROV, Yokohama-shi (JP)

(73) Assignees: SHIBAURA MECHATRONICS CORPORATION, Yokohama-shi (JP); TOSHIBA MEMORY CORPORATION, Minato-ku (JP)

(21) Appl. No.: 15/715,966

(22) Filed: Sep. 26, 2017

Related U.S. Application Data
(63) Continuation of application No. PCT/JP2016/060820, filed on Mar. 31, 2016.

(30) Foreign Application Priority Data
Mar. 31, 2015 (JP) 2015-074109
Mar. 25, 2016 (JP) 2016-062077

(51) Int. Cl. C23C 14/04; B29C 33/38; G03F 7/00; B29C 59/02

(52) U.S. Cl. CPC C23C 14/042; G03F 7/0002; B29C 33/3842; B29C 59/022

(57) ABSTRACT

According to one embodiment, an imprint template manufacturing apparatus includes a support unit, a vaporization unit, and an adhesion preventing plate. The support unit supports a template that includes a base having a main surface, and a convex portion provided on the main surface and having an end surface. A concavo-convex pattern to be pressed against a liquid material to be transferred is formed on the end surface. The support unit supports the template with the convex portion facing downward. The vaporization unit is located below the template on the support unit and configured to vaporize a liquid-repellent material. The adhesion preventing plate is located below the template on the support unit and configured to allow the liquid-repellent material vaporized to adhere to the side surface of the convex portion of the template and to prevent it from adhering to the concavo-convex pattern.

### CROSS-REFERENCE TO THE RELATED APPLICATION

This application is based upon and claims the benefit of priority from International Application No. PCT/JP2016/060820, filed on Mar. 31, 2016; Japanese Patent Application No. 2015-074109, filed on Mar. 31, 2015 and Japanese Patent Application No. 2016-062077, filed on Mar. 25, 2016; the entire contents of all of which are incorporated herein by reference.

### FIELD

Embodiments described herein relate generally to an imprint template manufacturing apparatus.

### BACKGROUND

In recent years, an imprinting method has been proposed as a method for forming a fine pattern on a workpiece such as a semiconductor substrate. In this imprinting method, a mold (master) having a concavo-convex pattern formed thereon is pressed against the surface of a liquid material to be transferred (for example, photocurable resin) such as a resist applied on a workpiece. Then, light is irradiated from the surface opposite to the surface on which the pattern is formed, and the mold is removed from the cured material to be transferred. Thereby, the concavo-convex pattern is transferred to the material to be transferred. A template is used as a mold to be pressed against the surface of the liquid material to be transferred, This template is also called mold, imprint mold or stamper.

The template is formed of quartz or the like having high translucency so that light such as ultraviolet rays is easily transmitted in a step (transfer step) of curing the material to be transferred. The template is provided with a convex portion (convexity) on its main surface, and a concavo-convex pattern to be pressed against the liquid material to be transferred is formed on the convex portion. For example, the convex portion having a concavo-convex pattern is referred to as “mesa portion”, and a portion other than the mesa portion on the main surface of the template is referred to as “off-mesa portion”.

However, when the template is pressed against the liquid material to be transferred, the liquid material to be transferred seeps out from the end of the convex portion. Although it is a small amount, the liquid material to be transferred having seeped out may sometimes be raised along the side surface (side wall) of the convex portion. The material to be transferred adhering to the side surface of the convex portion is cured in that state by light irradiation. Accordingly, when the template is separated from the material to be transferred, a raised portion is present in the material to be transferred, resulting in the occurrence of pattern abnormality.

In addition, when the template is separated from the material to be transferred, the raised portion of the material to be transferred sticks to the template. It thereafter may drop on the material to be transferred at some timing and become dust. If the template is pressed onto the dropped dust, the concavo-convex pattern on the template may be damaged, or the dropped dust enters in the concavo-convex pattern on the template and becomes foreign matter. Thus, template abnormality occurs. Further, if pattern transfer is continuously performed using a template having such a damaged concavo-convex pattern or a template into which a foreign matter has entered, a defect is generated in the pattern of the material to be transferred, thus resulting in the occurrence of pattern abnormality.

### BRIEF DESCRIPTION OF THE DRAWINGS

FIG. 1 is a diagram illustrating a schematic configuration of an imprint template manufacturing apparatus according to a first embodiment;

FIG. 2 is a cross-sectional view schematically illustrating an uncoated template according to the first embodiment;

FIG. 3 is a plan view schematically illustrating a support structure of an adhesion preventing plate according to the first embodiment;

FIG. 4 is a plan view schematically illustrating a modified example of the support structure of the adhesion preventing plate of the first embodiment;

FIG. 5 is an explanatory diagram for explaining a coating process using the adhesion preventing plate of the first embodiment;

FIG. 6 is an explanatory diagram for explaining an imprint process according to the first embodiment;

FIG. 7 is a cross-sectional view illustrating a schematic configuration of an adhesion preventing plate according to a second embodiment;

FIG. 8 is a cross-sectional view illustrating a schematic configuration of an adhesion preventing plate according to a third embodiment; and

FIG. 9 is a cross-sectional view illustrating a schematic configuration of an adhesion preventing plate according to a fourth embodiment.

### DETAILED DESCRIPTION

According to one embodiment, an imprint template manufacturing apparatus includes a support unit, a vaporization unit, and an adhesion preventing plate. The support unit supports a template that includes a base having a main surface, and a convex portion provided on the main surface and having an end surface on a side opposite to the main surface. A concavo-convex pattern to be pressed against a liquid material to be transferred is formed on the end surface. The support unit supports the template with the convex portion facing downward. The vaporization unit is located below the template supported by the support unit and configured to vaporize a liquid-repellent material that repels the liquid material to be transferred. The adhesion preventing plate is located below the template supported by the support unit and configured to allow the liquid-repellent material vaporized to adhere to the side surface of the convex portion of the template supported by the support unit and to prevent it from adhering to the concavo-convex pattern.

### First Embodiment

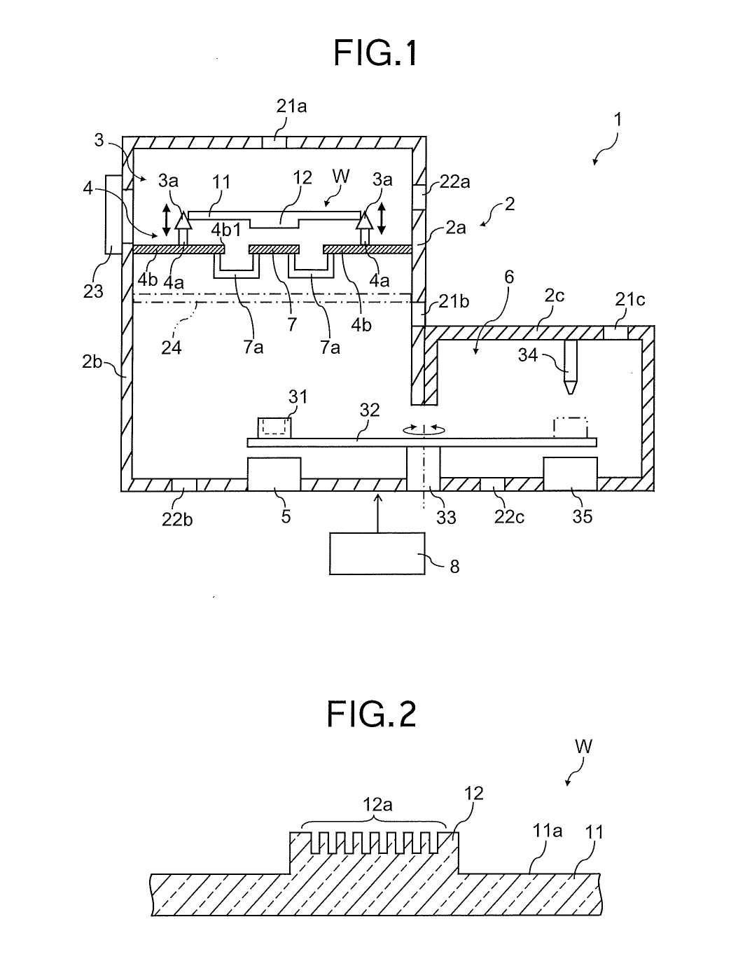

A first embodiment will be described with reference to FIGS. 1 to 6. The imprint template manufacturing apparatus according to the first embodiment is an example of a vapor deposition coating apparatus that deposits a liquid-repellent material on a template to coat a part of the template.

As illustrated in FIG. 1, an imprint template manufacturing apparatus 1 according to the first embodiment includes a treatment tank 2 for treating a template w, a support unit 3 configured to support the unprocessed template W, a moving mechanism 4 configured to move the support unit 3 in the height direction, a vaporization unit 5 configured to vaporize a liquid-repellent material in a liquid form, a supply unit 6 configured to supply the liquid-repellent material to the vaporization unit 5, an adhesion preventing plate 7 configured to prevent the adhesion of the liquid-repellent material to the template W, and a controller 8 configured to control each unit.

First, the template W to be coated will be described with reference to FIG. 2. As illustrated in FIG. 2, the template W includes a base 11 haying a main surface 11a and a convex portion 12 provided on the main surface 11a of the base 11.

The base 11 has translucency, and is formed in a plate shape in which the main surface 11a is a flat surface. The plate shape of, the base 11 is, for example, square or rectangular; however, the shape is not particularly limited. For example, a substrate having high translucency such as a quartz substrate can be used as the base 11. Note that, in an imprint process, light such as ultraviolet rays is irradiated to the opposite surface of the main surface 11a.

The convex portion 12 has translucency, and is integrally formed with the base 11 from the same material. A concavo-convex pattern 12a is formed on an end surface of the convex portion 12, that is, the surface (upper surface in FIG. 2) opposite to the main surface 11a side of the convex portion 12. The concavo-convex pattern 12a is pressed against a liquid material to be transferred (for example, photocurable resin). The pattern region in which the concavo-convex pattern 12a is formed on the end surface of the convex portion 12 is, for example, a square or rectangular region; however, the shape is not particularly limited

Referring back to FIG. 1, the treatment tank 2. includes a treatment chamber 2a, a vaporization chamber 2b, and a supply chamber 2c. The treatment chamber 2a, the vaporization chamber 2b, and the supply chamber 2c are box-shaped. The treatment chamber 2a is provided with an air supply port 21a in its upper surface and an exhaust port 22a in its side surface. The vaporization chamber 2b is provided with an air supply port 21b in its side surface and an exhaust port 22b in its bottom surface. Similarly, the supply chamber 2c is provided with an air supply port 21c in its upper surface and an exhaust port 22c in its bottom surface. Thereby, in the treatment chamber 2a, the vaporization chamber 2b, and the supply chamber 2c, air having passed through a filter (for example, ULPA filter or HEPA filter) flows from the air supply port 21a, 21b, and 21c to the exhaust ports 22a, 22b, and 22c, and the inside of the treatment chamber 2a is kept clean by a laminar flow. Note that the air supply and exhaust can be stopped during a vapor deposition coating process so as not to interrupt the flow of the vapor of the liquid-repellent material.

It is also possible to perform vapor deposition while supplying air through the air supply port 21a provided in the upper surface of the treatment chamber 2a during the vapor deposition coating. As illustrated in FIG. 1, the air supply port 21a is provided to a position facing the back surface of the template W (the surface opposite to the surface on which the concavo-convex pattern 12a is formed). Therefore, vapor deposition can be performed while the template VI is being cooled from the back surface during the vapor deposition coating. The vaporized liquid-repellent material (vapor) contacts the template w having a relatively low temperature in the treatment chamber 2a and adheres thereto. Thus, it is possible to improve the adhesion rate of the vaporized liquid-repellent material (vapor).

Besides, for example, when there is a space between the template W and the adhesion preventing plate 7 and the inner wall of the treatment chamber 2a such as when the template W and the adhesion preventing plate 7 are held by one or more arms on the inner wall of the treatment chamber 2a, the air supplied from the air Supply port 21a flows from the periphery of the template W to the lower space in the treatment chamber 2a. Then, a down flow is formed along the side wall of the treatment chamber 2a. This flow serves as an air curtain. Thus, it is possible to suppress the flow of the liquid-repellent material (vapor) from a container 31 toward the template K from diffusing toward the side wall of the treatment chamber 2a and to suppress the vaporized liquid-repellent material (vapor) from adhering to the inner wall of the treatment chamber 2a. This reduces the consumption of the liquid-repellent material on the inner wall of the treatment chamber 2a and improves the vapor deposition rate of the liquid-repellent material (vapor) with respect to the template W. When the down-flow air collides against the bottom surface of the treatment chamber 2a, a flow of air currents rising from the bottom surface toward the template W is generated, which assists the flow of the liquid-repellent material (vapor). In addition, the upward and downward currents promote the turbulence and stirring of the liquid-repellent material (vapor). In this manner, by generating a flow of air currents, it is possible to improve the deposition rate of the liquid-repellent material (vapor) with respect to the template W.

A door 23 for loading and unloading the template W is formed on the side surface of the treatment chamber 2a. A shutter 24 is provided to separate the treatment chamber 2a from the vaporization chamber 2b so as to be opened and closed. The shutter 24 is formed in a plate shape. The shutter 24 is inserted through a gap provided at the boundary between the treatment chamber 2a and the vaporization chamber 2b, and moved in the horizontal direction to be opened and closed, when the template W is loaded and unloaded, the door 23 is opened. At this time, the shutter 24 is closed before the door 23 is opened so as to prevent foreign matter (for example, dust, mote, etc.) from entering the vaporization chamber 2b via the treatment chamber 2a from the door 23 opened. When the door 23 is closed, normally, the shutter 24 is open.

The support unit 3 includes a plurality (for example, three or four) of support members 3a such as pins, and supports the template W by the support members 3a with the convex portion 12 of the template W facing downward. Each of the support members 3a has an inclined surface that comes in contact with the lower corner of the outer periphery of the template W. The support members 3a support the template W with the inclined surface in contact with the lower corner of the outer periphery of the template W.

The moving mechanism 4 has a plurality of height adjusting mechanisms 4a. Each of the height adjusting mechanisms 4a supports corresponding one of the support members 3a and guides it in the height direction (vertical direction) to move it. The height adjusting mechanisms 4a are fixed to a support plate 4b horizontally provided on the side wall inside the treatment chamber 2a. The moving mechanism 4 is electrically connected to the controller 8, and is driven under the control of the controller 8. As the moving mechanism 4, various moving mechanisms such as, for example, a feed screw moving mechanism and an air cylinder can be used.

The vaporization unit 5 is provided to the bottom surface of the vaporization chamber 2b. The vaporization unit 5 is a heater that heats the liquid-repellent material until it vaporizes. The vaporization unit 5 is electrically connected to the controller 3, and is driven under the control of the controller 8. The vapor of the liquid-repellent material is introduced to the treatment chamber 2a by generating vapor directly under the template W. Besides, for example, vapor may be generated by a vaporization unit provided outside the vaporization chamber 2b and introduced to the treatment chamber 2a.

The supply unit 6 includes the container 31 that individually stores a liquid-repellent material in a liquid form, a rotation arm 32 that supports the container 31 at one end, a rotation mechanism 33 that rotates the rotation arm 32 about its center as a rotation axis, a supply head 34 configured to supply the liquid-repellent material to the container 31 on the rotation arm 32, and a cooling unit 35 configured to cool the container 31 on the rotation arm 32.

The container 31 is a heat-resistant container (storage) having an opening in the upper surface. The container 31 is positioned at one end of the rotation arm 32 and fixed to the upper surface of the rotation arm 32. Normally, the container 31 is replaced with a new one for each deposition process on the template W. Therefore, at the time of loading or unloading the template W, for example, the container 31 is replaced in the supply chamber 2c, and a liquid-repellent material in a liquid form is supplied to the container 31 from the supply head 34 located right above the container 31.

Incidentally, although the shutter 24 is used to prevent foreign matter from entering the container 31, it is not so limited. For example, instead of or in addition to the shutter 24, a detachable cover for covering the container 31 may be provided to prevent foreign matter from entering the container 31.

The rotation arm 32 is arranged horizontally on the rotation mechanism 33 so as to rotate about its center as a rotation axis within a plane. In the case of vaporizing a liquid-repellent material in a liquid form in the container 31, the rotation arm 32 is rotated by the rotation mechanism 33 such that the container 31 it holds is located above the vaporization unit 5. Besides, at the time of replacing the container 31, the rotation arm 32 is rotated by the rotation mechanism 33 such that the container 31 is located above the cooling unit 35.

The rotation mechanism 33 supports the center of the rotation arm 32, and rotates the rotation arm 32 about the center as a rotation axis. Further, the rotation mechanism 33 is capable of adjusting the height of the rotation arm 32 by moving it in the height direction. The height of the rotation arm 32 is adjusted to a height that allows the vaporization unit 5 to heat the container 31 on the rotation arm 32 and that allows the cooling unit 35 to cool the container 31 on the rotation arm 32. The rotation mechanism 33 is electrically connected to the controller 8, and is driven under the control of the controller 8.

The supply head 34 is a dispenser to drop a liquid-repellent material in a liquid form. The supply head 34 stores the liquid-repellent material supplied from a tank or the like outside the supply chamber 2c, and supplies the liquid-repellent material stored therein to the container 31 on the rotation arm 32 by dropping it thereto. The supply head 34 is electrically connected to the controller 8, and is driven under the control of the controller 8.

The liquid-repellent material in a liquid form has translucency, and is a material that repels the liquid material to be transferred (for example, photocurable resin). Examples of the material include a silane coupling agent. As the supply head 34, various supply heads can be used in addition to the dispenser configured to drop the liquid-repellent material.

The cooling unit 35 is provided to the bottom surface of the supply chamber 2c to cool the container 31 heated by the vaporization unit 5 in the vapor deposition coating process. The container 31 on the rotation arm 32 is cooled by the cooling unit 35 to a temperature at which it can be replaced. The cooling unit 35 is electrically connected to the controller 8, and is driven under the control of the controller 8.

The adhesion preventing plate 7 is provided in an opening 4b1 of the support plate 4b, and positioned below the convex portion 12 of the template W on the support unit 3. The adhesion preventing plate 7 is formed to have, for example, a square shape or a rectangular shape with a size equal to or larger than the area of a region where the concavo-convex pattern 12a is formed on the convex portion 12. The adhesion preventing plate 7 allows the liquid-repellent material (vapor) vaporized by the vaporization part 5 to adhere to the side surface of the convex portion 12 of the template w on the support unit 3 and prevent it from adhering to the concavo-convex pattern 12a on the convex portion 12. The adhesion preventing plate 7 and the convex portion 12 of the template W are separated in the height direction by such a distance that the liquid-repellent material adheres to at least the side surface of the convex portion 12 while avoiding the concavo-convex pattern 12a. As the adhesion preventing plate 7, for example, a plate of silicon, stainless steel, aluminum or the like can be used; however, the plate material is not particularly limited.

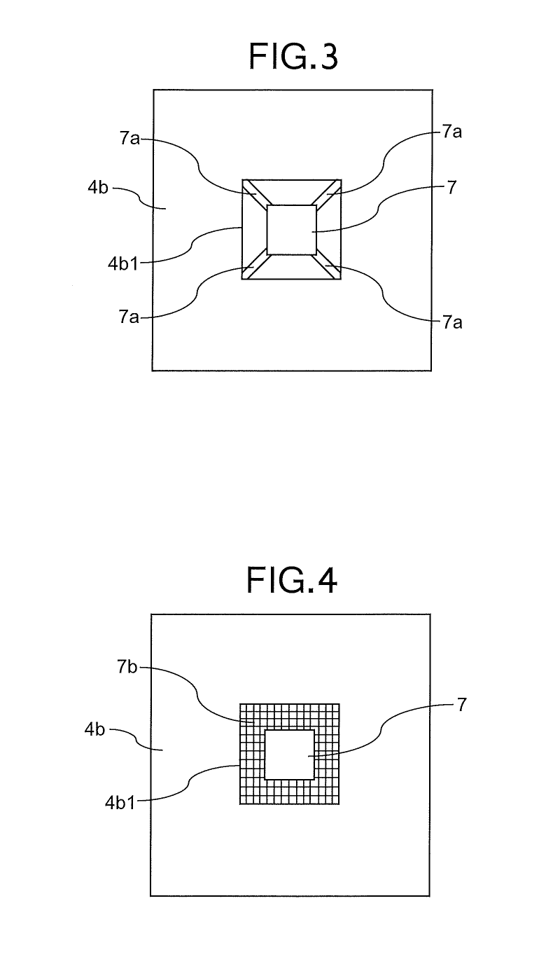

As illustrated in FIG. 3, the adhesion preventing plate 7 is positioned in the opening 4b1 of the support plate 4b and is supported by a plurality of (four in FIG. 3) support arms 7a fixed to the lower surface of the support plate 4b (see FIG. 1). The support arms 7a are formed so as not to hinder the vaporized liquid-repellent material (vapor) from passing between the support plate 4b and the adhesion preventing plate 7 as much as possible. For example, as illustrated in FIG. 1, the support arms 7a are formed such that a portion facing a space between the support plate 4b and the adhesion preventing plate 7 is separated downward from the space by a predetermined distance. With this, the vaporized liquid-repellent material (vapor) flows around the support arms 7a into the space between the support plate 4b and the adhesion preventing plate 7, thereby uniformly adhering to the side surface of the convex portion 12 of the template W on the support unit 3.

Although the adhesion preventing plate 7 has been described as being supported by a plurality of support arms (7a), it can be supported by a single support arm (7a). The number of support arms is not particularly limited. Further, as illustrated in FIG. 4, it is also possible to use a mesh member 7b that allows the vaporized liquid-repellent material (vapor) to pass through.

Besides, an arm may be provided to the side wall or the bottom surface (see FIG. 1) in the vaporization chamber 2b to support the adhesion preventing plate 7 by the arm. In the case of supporting the adhesion preventing plate 7 with this arm, the support plate 4b can be omitted. The arm has an up and down movement mechanism. The arm can perform up and down movement operation so as to position the adhesion preventing plate 7 at a height position where the adhesion preventing plate 7 is present in the vaporization chamber 2b when the shutter 24 is closed. Meanwhile, when the shutter 24 is open and the vapor deposition coating process is started, the arm can position the adhesion preventing plate 7 at a predetermined height position in the treatment chamber 2a.

When the support plate 4b is omitted, the support unit 3 for holding the template W and the moving mechanism 4 can be provided to a member such as one or more arms.

Referring back to FIG. 1, the controller 8 includes a microcomputer that intensively controls each unit, and a storage that stores processing information on the coating process, various programs, and the like (neither of which is illustrated). The controller 8 controls the moving mechanism 4, the vaporization unit 5, the supply unit 6, and the like based on the processing information and the various programs such that the liquid-repellent material is vapor-deposited on at least the side surface of the convex portion 12 of the template W supported by the support unit 3.

Next, the vapor deposition coating process performed by the imprint template manufacturing apparatus 1 will be described. The template W is placed on the support unit 3 in the treatment chamber 2a with the convex portion 12 facing downward. The door 23 is closed, and the shutter 24 is open such that the treatment chamber 2a and the vaporization chamber 2b are connected.

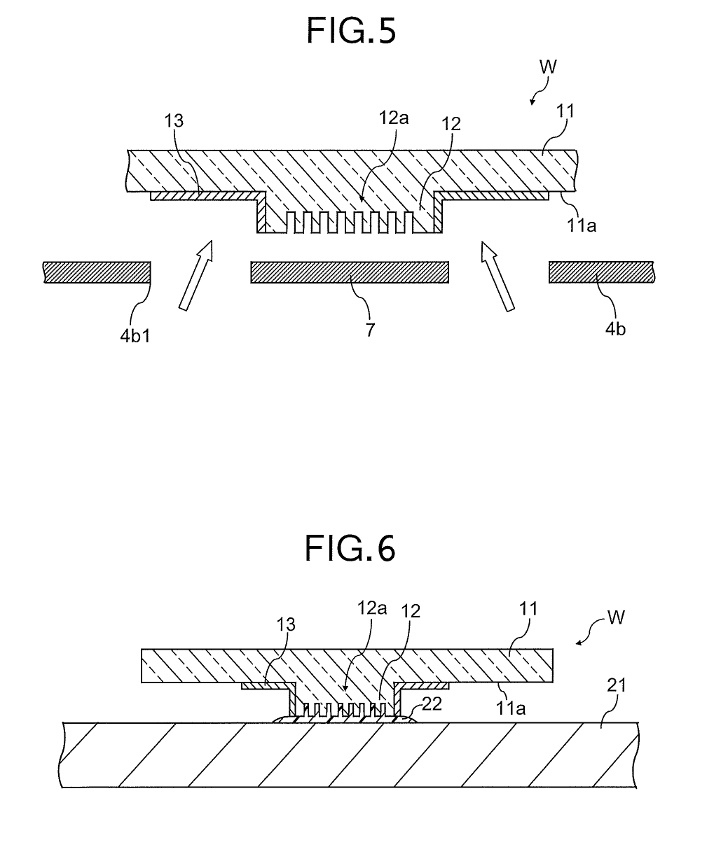

In the vapor deposition coating process, the container 31 located in the vaporization chamber 2b is heated by the vaporization unit 5, and the liquid-repellent material in a liquid form in the container 31 is vaporized. The vaporized liquid-repellent material (vapor) is introduced into, the treatment chamber 2a from the vaporization chamber 2b. As illustrated in FIG. 5, the vapor is interrupted by the adhesion preventing plate 7, and does not adhere to the concavo-convex pattern 12a of the convex portion 12 of the template W. The vapor gradually adheres to the side surface of the convex portion 12 and a part of the main surface 11a continuous to the side surface. When predetermined coating time has elapsed, a liquid-repellent layer 13 is formed on the entire side surface of the convex portion 12 and a part of the main surface 11a continuous to the side surface. Although the liquid-repellent layer 13 is described as being formed on the entire side surface of the convex portion 12, it is not so limited. The liquid-repellent layer 13 is only required to be formed on at least a part of the side surface of the convex portion 12.

The liquid-repellent layer 13 has translucency, and repels the liquid material to be transferred. The liquid-repellent layer 13 is provided on at least the side surface (side wall) of the convex portion 12 so as to avoid the concavo-convex pattern 12a on the convex portion 12, and further, is arranged in a predetermined region on the main surface 11a continuous to the side surface of the convex portion 12. Since the convex portion 12 has, for example, a square or a rectangular parallelepiped shape, the predetermined region around it on the main surface 11a is a quadrangular annular region in a planar view; however, the shape of the convex portion 12 and that of the annular predetermined region are not particularly limited.

In an imprint process, as illustrated in FIG. 6, the template W, on which the liquid-repellent layer 13 is formed, is treated such that the concavo-convex pattern 12a on the convex portion 12 is directed to a liquid material to be transferred 22 on a workpiece (for example, semiconductor substrate) 21, and is pressed against the liquid material to be transferred 22 on the workpiece 21. At this time, the liquid material to be transferred 22 seeps out from between the end surface of the convex portion 12 and the workpiece 21. However, since the liquid repellent layer 13 is formed on the side surface of the convex portion 12, the seeping liquid material to be transferred 22 is repelled by the liquid-repellent layer 13. In other words, the liquid-repellent layer 13 has the function of repelling the liquid material to be transferred 22. This suppresses the adhesion of the liquid material to be transferred 22 to the side surface of the convex portion 12. Thus, the liquid material to be transferred 22 is suppressed from being raised along the side surface of the convex portion 12

Next, in a state where the concavo-convex pattern 12a on the convex portion 12 is pressed against the liquid material to be transferred 22, the liquid material to be transferred 22 is irradiated with light such as ultraviolet rays from the surface opposite to the surface oh which the concavo-convex pattern 12a is formed. When the liquid material to be transferred 22 is cured by the light irradiation, the template W is separated from the cured material to be transferred 22, and the concavo-convex pattern 12a on the convex portion 12 is transferred to the liquid material to be transferred 22. In general, such an imprint process is repeated over the entire surface of the workpiece 21, and pattern transfer is repeatedly performed; however, the number of times of imprint is not particularly limited.

The liquid material to be transferred 22 is not limited to a liquid photocurable resin but may be, for example, a liquid thermosetting resin. In this case, the liquid material to be transferred 22 is cured, by heating it with a heating unit such as, for example, a heater or a light source.

As described above, according to the first embodiment, a liquid-repellent material is vapor-deposited on the side surface of the convex portion 12 of the template W so as to avoid the concavo-convex pattern 12a on the convex portion 12. Thereby, the liquid-repellent layer 13 can be formed on at least the side surface of the convex portion 12 so as to avoid the concavo-convex pattern 12a. With this, in the imprint process, the liquid material, to be transferred 22 that has seeped out from between the convex portion 12 of the template W and the workpiece 21 is repelled by the liquid-repellent layer 13. This suppresses the adhesion of the liquid material to be transferred 22 to the side surface of the convex portion 12. Thereby, it is possible to obtain the template W that can suppress a part of the cured material to be transferred 22 from being raised and suppress the occurrence of pattern abnormality. Moreover, it is possible to obtain the template W that can suppress the breakage of the template W and the biting of a foreign substance as well as suppressing the occurrence of pattern abnormality and template abnormality.

In addition, by the vapor deposition of the liquid-repellent material on the template W on the support unit 3 through the adhesion preventing plate 7, the liquid-repellent layer 13 can be readily formed on the side surface of the convex portion 12 so as to avoid the concavo-convex pattern 12a on the convex portion 12. Further, the separation distance in the height direction between the convex portion 12 of the template W and the adhesion preventing plate 7 can be adjusted by relatively moving the template W on the support unit 3 and the adhesion preventing plate 7 in the height direction. Thereby, the liquid-repellent material can be reliably adhered to the side surface of the convex portion 12 so as to avoid the concavo-convex pattern 12a on the convex portion 12. As a result, the liquid-repellent layer 13 can be reliably formed on the side surface of the convex portion 12.

In the imprint process, when the liquid material to be transferred 22 adheres to the side surface of the convex portion 12, generally, the template W is cleaned with a chemical solution to remove the liquid material to be transferred 22. However, according to the first embodiment, it is possible to suppress the material to be transferred 22 from adhering to the side surface of the convex portion 12 as described above. This eliminates the need of the cleaning step for removing the material to be transferred 22 from the side surface of the convex portion 12. Thereby, it is possible to eliminate the cleaning step of the template W after use as well as to prevent the pattern wear of the template W caused by the cleaning liquid and damage such as pattern collapse. As a result, the occurrence of template abnormality can be suppressed.

It is important to form the liquid-repellent layer 13 on at least the side surface of the convex portion 12 in such a way as to avoid the concavo-convex pattern 12 a so as not to form the liquid-repellent layer 13 on the concavo-convex pattern 12a. This is to avoid poor transfer (misprinting) of the concavo-convex pattern 12a with respect to the liquid material to be transferred 22. That is, the concavo-convex pattern 12a is a fine pattern having a width of nanometer size. Therefore, if the liquid-repellent layer 13 is formed on the concavo-convex pattern 12a, even if it is, a little, the accuracy of the dimensional width of the concavo-convex pattern 12a cannot be maintained due to the thickness of the liquid-repellent layer 13 added thereto. As a result, pattern abnormality occurs at the time of transfer.

### Second Embodiment

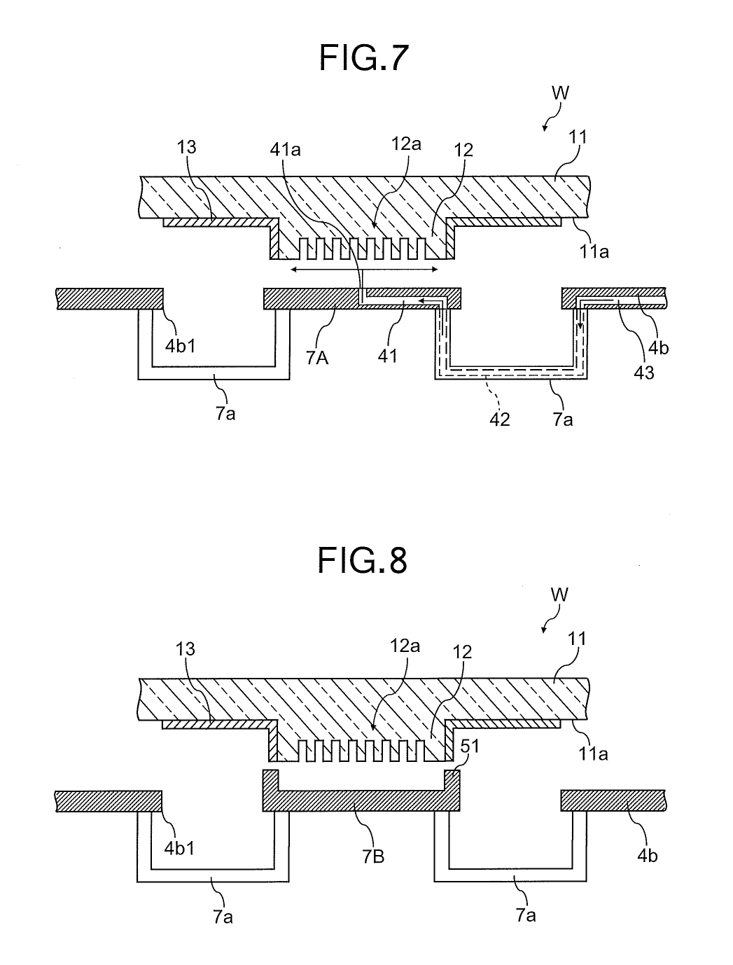

A second embodiment will be described with reference to FIG. 7. In the second embodiment, a description is given of differences from the first embodiment (adhesion preventing plate), and the same description will not be repeated.

As illustrated in FIG. 7, an adhesion preventing plate 7A of the second embodiment has an outlet 41a configured to blow out a gas (for example, an inert gas) into a space between the convex portion 12 of the template W on the support unit 3 and the adhesion preventing plate 7A. The outlet 41a is formed substantially at the center of the adhesion preventing plate 7A and is an opening at one end of a gas flow passage 41 formed in the adhesion preventing plate 7A. The gas flow passage 41 extends in the vertical direction inside the adhesion preventing plate 7A, bends at right angles and extends toward the outer periphery of the adhesion preventing plate 7A. The other end of the gas flow passage 41 is connected to a gas flow passage 42 formed in the support arm 7a. The gas flow passage 42 is connected to a gas flow passage 43 formed in the support plate 4b.

The gas supplied to the gas flow passage 43 from, for example, a supply tank (not illustrated) flows through the gas flow passages 42 and 41, and is blown out from the outlet 41a at one end of the gas flow passage 41. The blown gas flows from the inside to the outside in a space between the convex portion 12 of the template W on the support unit 3 and the adhesion preventing plate 7A. By the flow of the gas, it is possible to reliably suppress the adhesion of the vaporized liquid-repellent material (vapor) to the concavo-convex pattern 12a of the template W on the support unit 3. The flow rate of the gas at this time is set so as not to hinder vapor from adhering to the side surface of the convex portion 12 as well as to suppress the vapor from adhering to the concavo-convex pattern 12a of the template W on the support unit 3.

The number of the outlets (41a) is not particularly limited, and there may be a plurality of outlets (41a) in the adhesion preventing plate 7A. In this case, for example, the outlets (41a) may be arranged side by side along the outer periphery of the adhesion preventing plate 7A so as to avoid the center of the adhesion preventing plate 7A; however, the arrangement is not particularly limited.

As described above, according to the second embodiment, it is possible to achieve the same effects as those of the first embodiment. Further, gas is flown from the inside to the outside in a space between the convex portion 12 of the template W on the support unit 3 and the adhesion preventing plate 7A. This makes it possible to reliably suppress the vaporized liquid-repellent material (vapor) from adhering to the concavo-convex pattern 12a of the template W. Thus, it is possible to suppress the formation of the liquid-repellent layer 13 on the concavo-convex pattern 12a.

### Third Embodiment

A third embodiment will be described with reference to FIG. 8. In the third embodiment, a description is given of differences from the first embodiment (adhesion preventing plate), and the same description will not be repeated.

As illustrated in FIG. 8, an adhesion preventing plate 7B of the third embodiment includes a peripheral wall 51 having a height on the side of the template W on the support unit 3. The peripheral wall 51 is formed on the peripheral edge of the upper surface (the surface on the template W side) of the adhesion preventing plate 7B. The peripheral wall 51 is provided to the adhesion preventing plate 7B such that the inner wall thereof is located outside the position of the adhesion preventing plate 7B corresponding to the region where the concavo-convex pattern 12a of the template W on the support unit 3 is formed. That is, the inner wall of the peripheral wall 51 is located outside the concavo-convex pattern 12a of the template W on the support unit 3. This makes it possible to reliably suppress the vaporized liquid-repellent material (vapor) from adhering to the concavo-convex pattern 12a of the template W on the support unit 3.

As described above, according to the third embodiment, it is possible to achieve the same effects as those of the first embodiment. Further, the adhesion preventing plate 7B is provided with the peripheral wall 51 having a height on the side of the template w on the support unit 3. This makes it possible to reliably suppress the vaporized liquid-repellent material (vapor) from adhering to the concavo-convex pattern 12a of the template W. Thus, it is possible to suppress the formation of the liquid-repellent layer 13 on the concavo-convex pattern 12a.

### Fourth Embodiment

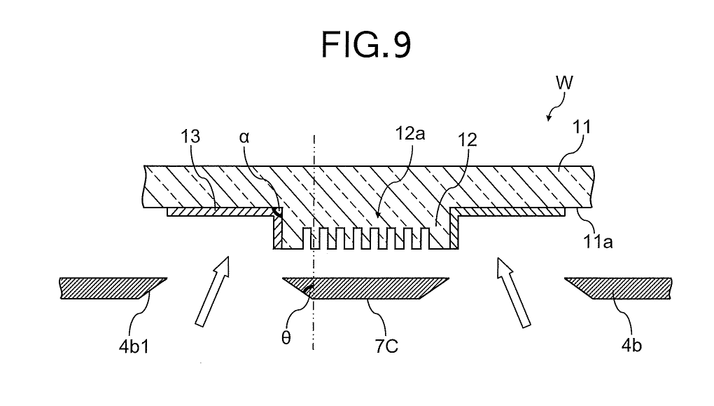

A fourth embodiment will be described with reference to FIG. 9. In the fourth embodiment, a description is given of differences from the first embodiment (adhesion preventing plate), and the same description will not be repeated.

As illustrated in FIG. 9, the lower surface of an adhesion preventing plate 7C of the fourth embodiment (the surface on the container 31 side) is smaller than the upper surface (the surface on the side of the template W on the support unit 3). The side surface of the adhesion preventing plate 7C continuous to the upper surface is inclined. The inclined surface is inclined so as to gradually become higher in the horizontal direction and along a direction toward the outside of the adhesion preventing plate 7C. As a result, a flow of the liquid-repellent material (vapor) is generated along the side surface of the adhesion preventing plate 7C. This facilitates the adhesion of the liquid-repellent material (vapor) to the entire side surface of the convex portion 12 and a part of the main surface 11a of the base 11. The upper surface of the adhesion preventing plate 7C is formed in, for example, a square shape or a rectangular shape to have a size equal to or larger than the area of the region where the concavo-convex pattern 12a is formed on the convex portion 12.

The taper angle of the adhesion preventing plate 70 can be set to 60° or more and smaller than 90°. The taper angle refers to the angle at which an imaginary line extending in a direction perpendicular to the lower surface of the adhesion preventing plate 7C intersects the outline of the adhesion preventing plate 7C in the cross-sectional view thereof (the taper angle θ in FIG. 9). With this, it is possible to make the liquid-repellent material (vapor) enter the corner angle (corner angle α in FIG. 9) formed by the side surface of the convex portion 12 and the main surface 11a of the base 11 and easily adhere thereto while the liquid-repellent material (vapor) is prevented from going around to the end surface of the convex portion 12 (the surface on which the concavo-convex pattern 12a is formed).

Further, the side surface (inner peripheral surface) of the opening 4b1 of the support plate 4b is also inclined such that a flow of the liquid-repellent material (vapor) is generated along the side surface of the opening 4b1, and the liquid-repellent material (vapor) can be adhered to a desired region in the main surface 11a of the base 11. The side surface of the opening 4b1 is inclined so as to gradually become higher in the horizontal direction and along a direction toward the inside of the opening 4b1.

As described above, according to the fourth embodiment, it is possible to achieve the same effects as those of the first embodiment. Further, the side surface of the adhesion preventing plate 7C is inclined. Thereby, the liquid-repellent material (vapor) can be reliably adhered also to the corner angle formed by the side surface of the convex portion 12 and the main surface 11a of the base 11. In addition, the side surface of the opening 4b1 of the support plate 4b is also inclined. Thus, the liquid-repellent (vapor) can be reliably adhered to a desired region in the main surface 11a of the base 11.

### Other Embodiments

In each of the above embodiments, the liquid-repellent layer 13 is described as being formed on the entire side surface of the convex portion 12 and a part of the main surface 11a continuous to the side surface; however, it is not so limited. For example, the liquid-repellent layer 13 is only required to be formed on at least the side surface of the convex portion 12 so as to avoid the concavo-convex pattern 12a on the convex portion 12. The liquid-repellent layer 13 may be formed on a part of the end surface of the convex portion 12 or on the entire main surface 11a except the convex portion 12 in addition to the side surface of the convex portion 12. Further, the liquid-repellent layer 13 may be formed on a part of the end surface, of the convex portion 12 and on the entire main surface 11a except the convex portion 12 in addition to the side surface of the convex portion 12. Besides, it is only required to form the liquid-repellent layer 13 on a portion of the side surface of the convex portion 12 that comes in contact with the material to be transferred 22, and the liquid-repellent layer 13 may be formed on a part of the side surface of the convex portion 12

The liquid-repellent layer 13 is not limited to a single layer, and a stack, of a plurality of layers may be used. Further, the side surface (side wall) of the convex portion 12 may be perpendicular to the main surface 11a or may be inclined. In addition, the side surface of the convex portion 12 may be flat or may have a step.

In each of the embodiments, the adhesion preventing plate 7 is fixed and the template W is moved in the height direction by the moving mechanism 4; however, it is not so limited. It is sufficient if only the adhesion preventing plate 7 and the template W can be moved relatively in the height direction. For example, the template W may be fixed and the adhesion preventing plate 7 may be moved in the height: direction. In this case, as an example, each of the support arms 7a may be provided with the function of a lift up and down mechanism to move the adhesion preventing plate 7 in the height direction. Further, both the adhesion preventing plate 7 and the template W may be fixed. In this case, the height of the support members 3a that support the template W may be set such that the adhesion preventing plate 7 is separated from the template W by a predetermined distance.

Although a semiconductor substrate is exemplified as the workpiece 21, it is not limited thereto. The workpiece 21 may be a quartz substrate used as a replica template.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An imprint template manufacturing apparatus comprising:
a support unit configured to support a template that includes a base having a main surface, and a convex portion provided on the main surface and having an end surface on a side opposite to the main surface, wherein a concavo-convex pattern to be pressed against a liquid material to be transferred is formed on the end surface, the support unit supporting the template such that the convex portion faces downward;
a vaporization unit located below the template supported by the support unit and configured to vaporize a liquid-repellent material that repels the liquid material to be transferred; and
an adhesion preventing plate located below the template supported by the support unit and configured to allow the liquid-repellent material vaporized to adhere to a side surface of the convex portion of the template supported by the support unit and to prevent the liquid-repellent material vaporized from adhering to the concavo-convex pattern.

2. The imprint template manufacturing apparatus according to claim 1, further comprising a moving mechanism configured to move the template supported by the support unit and the adhesion preventing plate relatively in a height direction.

3. The imprint template manufacturing apparatus according to claim 2, further comprising a controller configured to control the moving mechanism such that a distance between the convex portion of the template supported by the support unit and the adhesion preventing plate in the height direction becomes a distance that allows the liquid-repellent material vaporized to adhere to at least the side surface of the convex portion so as to avoid the concavo-convex pattern.

4. The imprint template manufacturing apparatus according to claim 2, further comprising a controller configured to control the moving mechanism such that a distance between the convex portion of the template supported by the support unit and the adhesion preventing plate in the height direction becomes a distance that allows the liquid-repellent material vaporized to adhere to the side surface and the end surface of the convex portion so as to avoid the concavo-convex pattern.

5. The imprint template manufacturing apparatus according to claim 1, wherein an area of the adhesion preventing plate that faces the concavo-convex pattern is equal to or larger than an area of a region where the concavo-convex pattern is formed on the end surface of the convex portion.

6. The imprint template manufacturing apparatus according to claim 1, wherein the adhesion preventing plate includes an outlet configured to blow out a gas into a space between the convex portion of the template supported by the support unit and the adhesion preventing plate.

7. The imprint template manufacturing apparatus according to claim 1, wherein the adhesion preventing plate includes a peripheral wall having a height on a side of the template supported by the support unit.

8. The imprint template manufacturing apparatus according to claim 1, wherein a side surface of the adhesion preventing plate is inclined.

9. The imprint template manufacturing apparatus according to claim 1, further comprising a treatment chamber that accommodates the support unit, the vaporization unit, and the adhesion preventing plate,
wherein the treatment chamber includes an air supply port arranged so as to face a surface of the template on a side opposite to the main surface.
